(19) United States
(12) Patent Application Publication
(10) Pub. No.: US 2016/0202092 A1
(43) Pub. Date: Jul. 14, 2016

(54) ACCESSORY STORAGE DEVICE FOR TEST INSTRUMENT

(71) Applicant: Fluke Corporation, Everett, WA (US)

(72) Inventor: Charles Elbert Marzette, Jr., Kirkland, WA (US)

(73) Assignee: Fluke Corporation, Everett, WA (US)

(21) Appl. No.: 14/594,053

(22) Filed: Jan. 9, 2015

(51) Int. Cl. G01D 11/24; G01R 15/12

(52) U.S. Cl. CPC G01D 11/24; G01R 15/125

(57) ABSTRACT

A holster for a portable test instrument (e.g., a multimeter) or the test instrument itself includes a frontward-facing portion, a rearward-facing portion that defines a rearward plane of the holster or instrument, and a low-profile accessory storage device (e.g., a hanger or one or more mounting holes) configured to receive at least a portion of an accessory (e.g., a probe that is usable with the portable test instrument) and releasably attach the accessory to the holster or instrument. The accessory storage device may be disposed within the rearward-facing portion such that the low-profile accessory storage device does not extend beyond the rearward plane of the holster or instrument. The accessory storage device also may include an elongate slot with a magnet for magnetic engagement with an elongate metal plate on the accessory.

### BACKGROUND

Portable measurement instruments, such as digital multimeters, provide value to technicians that wish to take measurements in the field. For example, a technician that wishes to take voltage measurements can use a digital multimeter with attached probes to measure voltage. Although prior devices have provided means for attaching probes to portable measurement instruments for storage purposes, prior attachment means have been overly bulky, such that even when the probes are not being stored on the instrument, the attachment means themselves create a large device profile that can make the instrument difficult to hold comfortably.

Whatever the benefits of prior devices, they fail to achieve all the advantages of the embodiments described herein.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, a holster for a portable test instrument (e.g., a multimeter) comprises a frontward-facing portion configured to receive a portable test instrument, a rearward-facing portion that defines a rearward plane of the holster, and a low-profile accessory storage device configured to receive at least a portion of an accessory of the portable test instrument (e.g., a probe that is usable with the portable test instrument) and releasably attach the accessory to the holster. In this aspect, the low-profile accessory storage device is disposed within the rearward-facing portion such that the low-profile accessory storage device does not extend beyond the rearward plane of the holster. The rearward-facing portion may include a perimeter edge that defines the rearward plane of the holster. The perimeter edge may include a ridge, and the rearward plane may be defined by an upper portion of the ridge. The holster may include a tilt stand configured to accommodate releasable attachment of the accessory to the low-profile accessory storage device while the tilt stand is in an open position or a closed position.

In another aspect, a portable test instrument (e.g., a multimeter) comprises a frontward-facing portion, a rearward-facing portion that defines a rearward plane of the portable test instrument, and a low-profile accessory storage device configured to receive at least a portion of an accessory (e.g., a probe that is usable with the portable test instrument) and releasably attach the accessory to the portable test instrument. In this aspect, the low-profile accessory storage device is disposed within the rearward-facing portion such that the low-profile accessory storage device does not extend beyond the rearward plane of the portable test instrument. The rearward-facing portion may include a rearward-facing portion of a housing or cover of the portable test instrument.

In such aspects, a low-profile accessory storage device may include an accessory hanger, which may be configured to engage a clip disposed on the accessory to securely and releasably attach the accessory to the accessory hanger. The accessory hanger may include a keyed slot configured to engage a rail disposed on the accessory to securely and releasably attach the accessory to the accessory hanger. As another example, a low-profile accessory storage device may include a mounting hole. The mounting hole may be configured to engage a mounting post disposed on the accessory to securely and releasably attach the accessory to the holster. As another example, a low-profile accessory storage device may include a plurality of mounting holes configured to engage a corresponding plurality of mounting posts disposed on the accessory to securely and releasably attach the accessory to the holster. As another example, a low-profile accessory storage device may be configured to magnetically engage the accessory to releasably attach the accessory to the portable test instrument.

### DESCRIPTION OF THE DRAWINGS

The foregoing aspects and many of the attendant advantages of this disclosure will become more readily appreciated as the same become better understood by reference to the following detailed description, when taken in conjunction with the accompanying drawings, wherein:

FIG. 1 is a perspective view of an instrument in a holster having accessory storage devices, in accordance with the present disclosure;

FIG. 2 is a partial perspective view of an instrument in a holster having integrated accessory storage devices, in accordance with the present disclosure;

FIG. 3 is a perspective view of a test lead probe with a removable clip that may be used in combination with accessory storage devices such as those shown in FIGS. 1 and 2, in accordance with the present disclosure;

FIG. 4 is a perspective view of a probe with mounting posts, in accordance with the present disclosure;

FIG. 5 is a partial perspective view of an instrument in a holster having integrated accessory storage devices in the form of mounting holes that may be used in combination with an accessory such as the probe shown in FIG. 4, in accordance with the present disclosure;

FIG. 6 is a partial perspective view of an instrument having a probe with a T-rail and a corresponding accessory storage device comprising a keyed slot, in accordance with the present disclosure; and

FIG. 7 is a partial perspective view of an instrument having a probe with a metal plate and a corresponding magnetic probe holder in accordance with the present disclosure.

### DETAILED DESCRIPTION

Embodiments of the present disclosure are generally directed to accessory storage devices for portable instruments, such as digital multimeters. Described embodiments allow accessories (e.g., instrument probes, such as test lead probes) to be stored in unobtrusive locations (e.g., on the reverse side of a digital multimeter) with accessory storage devices having slim profiles that are less bulky than traditional accessory mounts and make the instrument easier to hold.

The detailed description set forth below in connection with the appended drawings, where like numerals reference like elements, provides a description of various embodiments of the disclosed subject matter and is not intended to represent an exhaustive description of all possible embodiments. Each embodiment described in this disclosure is provided merely as an example or illustration and should not be construed as preferred or advantageous over other embodiments or to limit the disclosure to the precise forms disclosed. Similarly, any steps described herein may be interchangeable with other steps, or combinations of steps, in order to achieve the same or substantially similar result. It will be apparent to one skilled in the art that many embodiments of the present disclosure may be practiced without some or all of the specific details set forth herein. Further, it will be appreciated that embodiments of the present disclosure may employ any combination of features described herein.

Although accessory storage devices described herein may be referred to as “probe holders” for ease of discussion, they may hold or otherwise allow storage of other suitably configured accessories that are not necessarily probes. Described accessory storage devices can be integrated into or attached to a holster from which an instrument can be readily removed. Alternatively, described accessory storage devices can be formed as integral parts of a cover (e.g., an overmolded portion) of an instrument or the housing of an instrument, or be attached directly to such a cover or housing. A holster, cover, or housing in which described accessory storage devices are provided may be constructed using any suitable materials or processes (e.g., injection molding, 3D printing, or the like). For example, the holster or cover may be injection-molded using any suitable injection-molding materials such as semi-flexible thermoplastic, thermoelastic, or elastomeric materials. The housing, holster, or cover may be of any suitable shape (e.g., substantially rectangular) to accommodate the instrument.

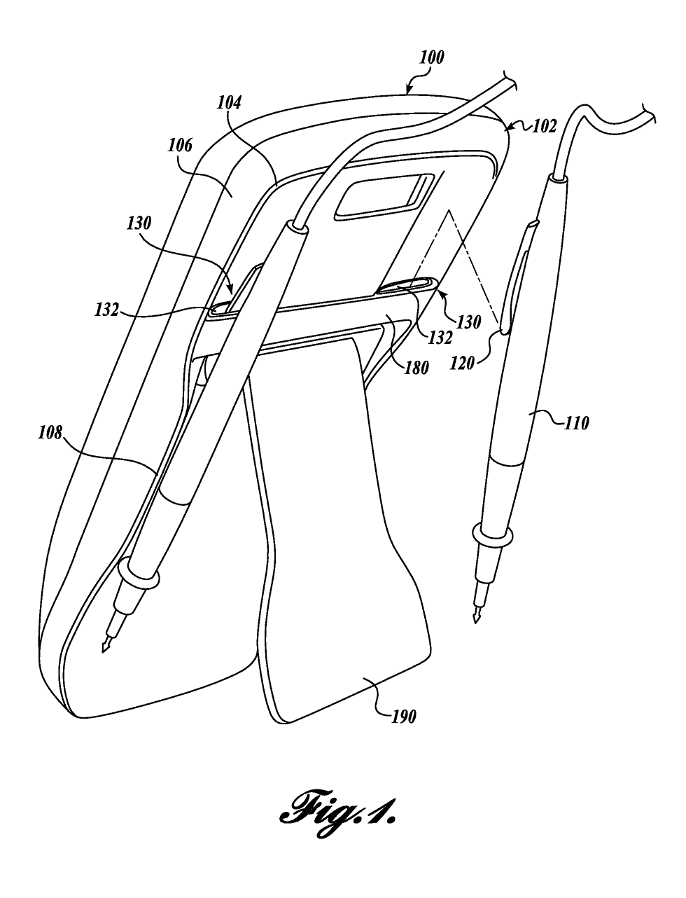

FIG. 1 illustrates accessory storage devices in a holster 102 attached to a portable handheld instrument 100 (e.g., a test instrument such as a digital multimeter). In the example shown in FIG. 1, the rearward-facing portion of the holster 102 is shown. (The forward-facing portion (not shown) of the holster 102 holds the instrument 100.) The rearward-facing portion of the holster 102 includes a rearward perimeter edge 104 that defines an extent of a side surface 106 around the perimeter of the holster 102. In this example, a user of the instrument can hold the instrument by grasping the sides of the instrument 100 and/or the side surface 106 of the holster 102 with a single hand (not shown), with the user's palm facing the rearward-facing side of the holster 102. The rearward-facing portion of the holster 102 also includes integrated accessory storage devices in the form of accessory hangers 130. The accessory hangers 130 are configured to receive a clip 120 mounted on an accessory such as a test lead probe 110. As shown, the accessory hangers 130 are defined by through-holes that pass completely behind a transverse member 180 of the holster 102 to allow the clip 120 to attach the probe 110 to the holster 102. In other embodiments, depending on the type and form of the clip 120, the through-holes in the accessory hangers 130 may not pass completely behind the transverse member 180 but instead form a recess behind the transverse member to receive the clip 120.

In the example shown in FIG. 1, the perimeter edge 104 defines a plane of the rearward-facing portion of the holster 102. The accessory hangers 130 do not extend beyond the plane defined by the upper portion of the perimeter edge 104 of the holster 102, so as to provide a low-profile accessory storage device that does not interfere with a typical user's grip, if the user were to grip the holster in the area of the accessory storage device. Although the perimeter edge 104 is depicted as including a ridge with a protruding portion 108 in this example, the protruding portion 108 is not required. The perimeter edge 104 can be configured in other ways, e.g., without a ridge and/or without any significant protruding portions 108.

The clip 120 may be formed of flexible material (such as flexible plastic) to allow the distal end of the clip 120 to move away from the barrel of the probe 110 to permit insertion of the clip into the probe hangers 130 through the through-holes 132, and then return to a position that is flush against the barrel of the probe 110 to securely and releasably attach the probe 110 to the transverse member 180. The design of the clip 120 and/or the corresponding hanger 130 can be modified to suit particular accessories and clips, such as by modifying the size or shape of the clip 120 or the through-holes 132 to fit more or less snugly together, or configuring the clip 120 such that the distal end of the clip 120 is flush against or spaced apart from the barrel of the probe 110. In the example shown in FIG. 1, the holster 102 has an optional tilt stand 190 (shown in an open position) that can be used to position the instrument in a standing position when the instrument is not being held. The tilt stand 190 can be returned to a closed position against the rearward-facing side of the holster 102 when the tilt stand 190 is not in use. The tilt stand 190 may be shaped to accommodate releasable attachment of the probes 110 to the probe hangers 130 while the tilt stand 190 is in the open position or the closed position.

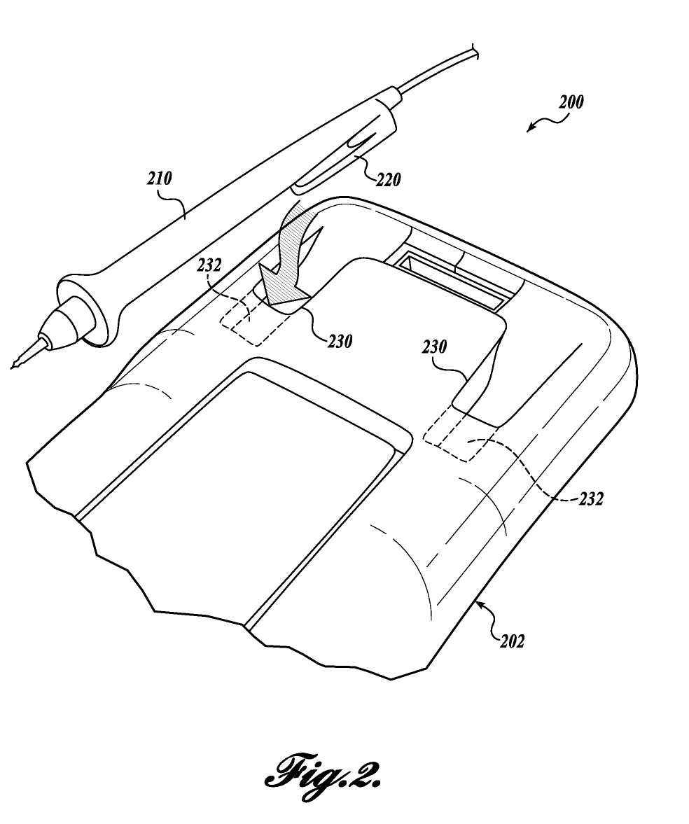

FIG. 2 illustrates other low-profile accessory storage devices for a portable handheld instrument 200. In the example shown in FIG. 2, the instrument 200 is shown in a holster 202 with integrated accessory storage devices in the form of accessory hangers 230 configured to receive a clip 220 mounted on an accessory such as a probe 210. As shown, the accessory hangers 230 are defined in part by recessed areas 232 of sufficient width and depth to allow the clip 220 to extend into and thereby securely and releasably attach the probe 210 to the holster 202. The accessory hangers 230 do not protrude from the plane of the rearward-facing portion of the holster 202 and thereby provide another example of low-profile accessory storage devices that do not interfere with a typical user's grip.

In the example shown in FIG. 2, the clip 220 is formed such that the distal end of the clip 220 is spaced apart from the barrel of the probe 210. However, the distal end of the clip 220 may still press against an interior surface of the accessory hanger 230 within the recessed area 232 to securely and releasably attach the probe 210 to the holster 202, depending on the thickness of the holster material. The design of the clip 220 and the corresponding hanger 230 can be modified to suit particular accessories and clips, such as by modifying the size or shape of the clip 220 or the recessed areas 232 to allow the clip and the hanger 230 to fit more or less snugly together, or configuring the clip 220 such that the distal end of the clip 220 is more or less spaced apart from, or flush against, the barrel of the probe 210.

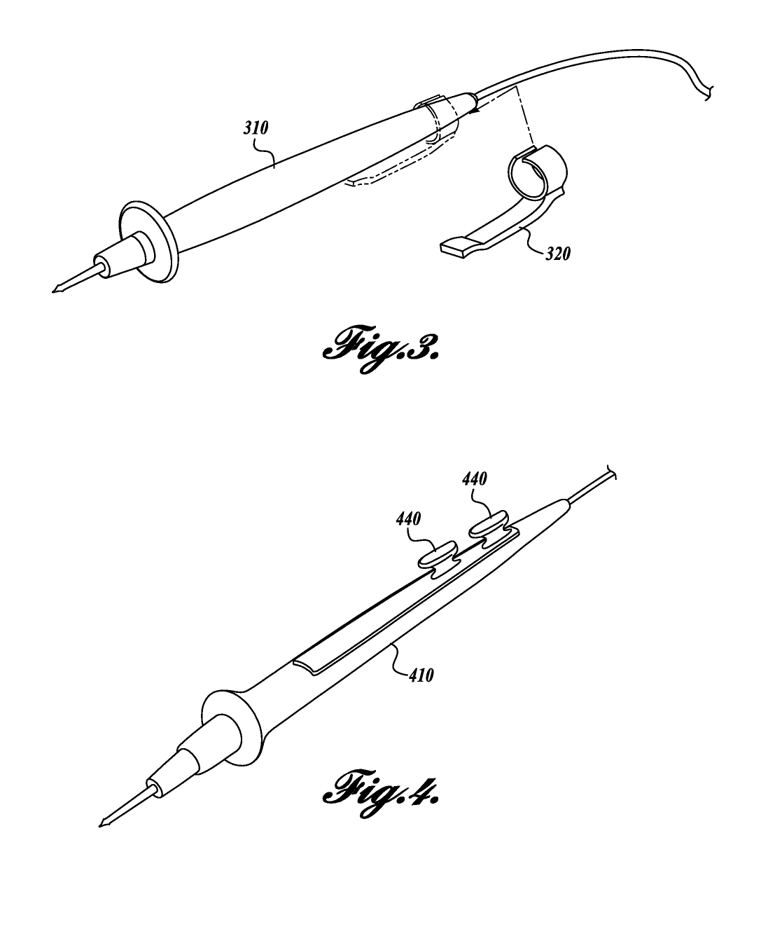

Referring to FIG. 3, a probe 310 with a removable clip 320 is illustrated. The removable clip 320 may be used to attach the probe 310 or another accessory to instruments having accessory storage devices, such as the accessory hangers 130 and 230 depicted in FIGS. 1 and 2, respectively. The design of the removable clip 320 can be modified to suit particular accessories and accessory storage devices, such as by modifying the size or shape of the clip 320 to fit more or less snugly in an accessory hanger, or configuring the distal end of the clip 320 to be flush against or spaced apart from a barrel of the probe 310 when the clip is attached to the probe 310. The removable clip 320 has the additional benefit of allowing accessories that may have been originally manufactured without integrated clips to be configured for use with accessory storage devices, such as the accessory hangers 130 and 230. As an example, a holster can be packaged with removable clips 320 to allow instruments with accessories that lack integrated clips to obtain the benefit of accessory storage devices provided by the holster.

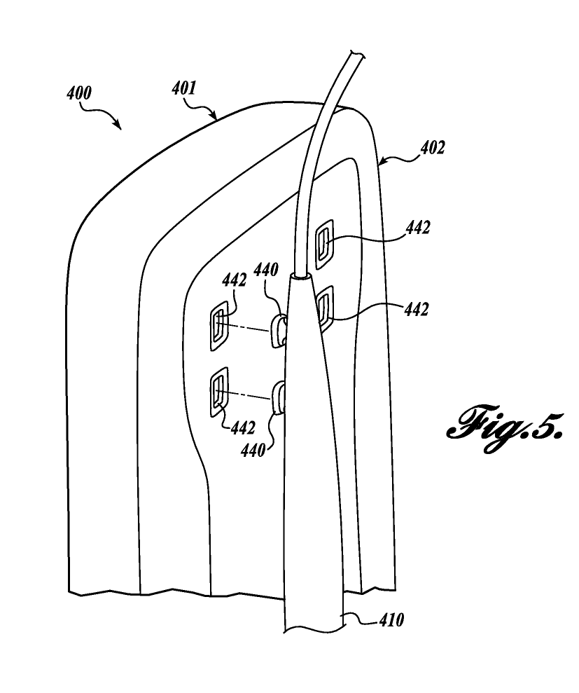

FIG. 4 illustrates a probe 410 with anvil-shaped mounting posts 440. The mounting posts 440 may be used to attach the probe 410 to instruments or holsters having suitably configured accessory storage devices. In the example shown in FIG. 5, a portable instrument 400 comprises a frontward-facing portion 401 and a rearward-facing portion 402. Mounting holes 442 are disposed in the rearward-facing portion 402 (e.g., a rearward-facing portion of a housing or cover of the instrument). The mounting holes 442 may be integrated into pliable material, such as a flexible plastic overmolding.

As shown, the mounting holes 442 are provided in pairs and are positioned and shaped to allow the mounting posts 440 to be pressed into a corresponding pair of mounting holes 442 for a secure fit. To accommodate the mounting posts 440, the rearward-facing portion 402 may define a void or recessed area behind the mounting holes 442 that allows the pressed-in mounting posts 440 to fit securely in the mounting holes 442. In the example shown in FIG. 5, the mounting holes 442 do not protrude from the plane of the rearward-facing portion 402 and thereby provide another example of low-profile accessory storage devices that do not interfere with a typical user's grip.

Although the examples shown in FIGS. 4 and 5 depict a probe 410 with two anvil-shaped mounting posts 440, more or fewer posts can be used. As another alternative, the mounting posts 440 can be replaced with mounting posts of different shapes or sizes, or other suitable mounting hardware, such as hooks or protrusions forming a detent. Further, although the rearward-facing portion 402 is depicted with four mounting holes 442, more or fewer mounting holes can be used. As another alternative, the mounting holes 442 can be replaced with mounting holes of different shapes or sizes, or other suitable mounting hardware such as rings or rails may be used in combination with the mounting posts 440 to securely and releasably attach accessories.

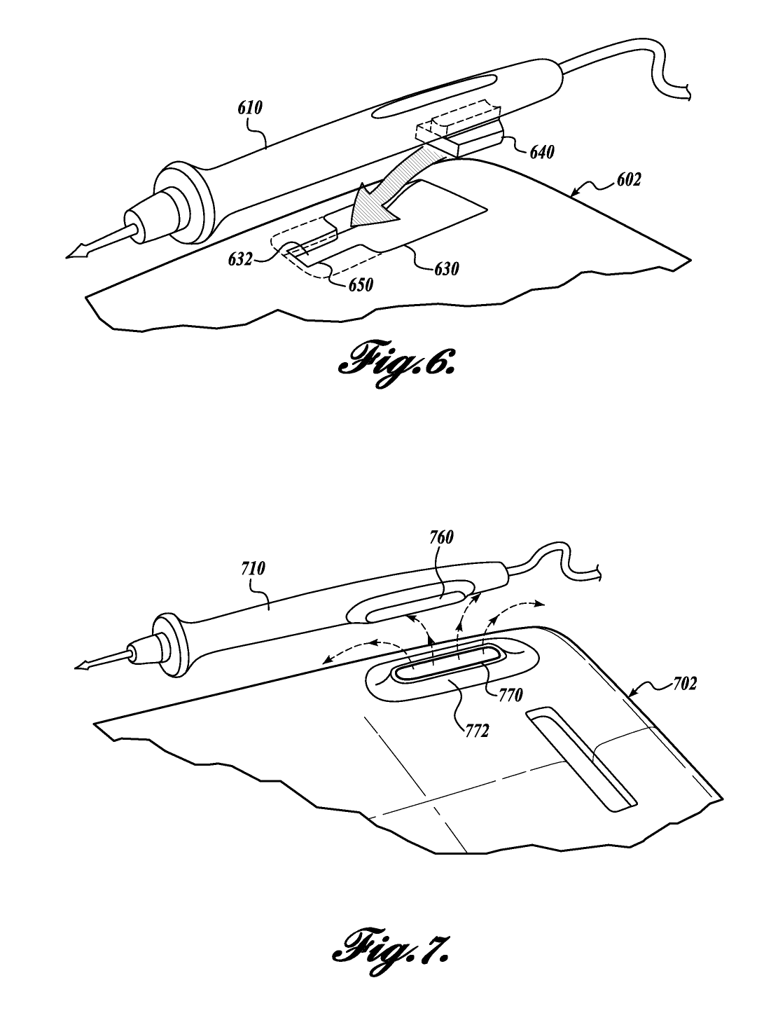

FIG. 6 illustrates another low-profile accessory storage device for a portable instrument. In the example shown in FIG. 6, a probe 610 includes an integrated T-rail 640. The accessory storage device is integrated into a holster 602 and is provided in the form of an accessory hanger 630 having a corresponding keyed slot 650 configured to receive the T-rail 640 of the probe 610. As shown, the accessory hanger 630 includes a recessed area 632 of sufficient width and depth to receive the T-rail 640 and thereby securely and releasably hold the probe 610. The design of the T-rail 640, the corresponding slot 650, and the recessed area 632 can be modified to suit particular accessories and accessory storage devices, such as by modifying the size or shape of the T-rail 640 to fit more or less snugly in the accessory hanger 630, or configuring the T-rail 640 to extend further or less far from the barrel of the probe 610. The accessory hanger 630 does not protrude from the plane of the rearward-facing portion of the holster 602 and thereby provides another example of a low-profile accessory storage device that does not interfere with a typical user's grip.

FIG. 7 illustrates yet another low-profile accessory storage device for a portable instrument. In the example shown in FIG. 7, a probe 710 includes an elongate metal plate 760. The accessory storage device is integrated into a holster 702 and is provided in the form of an elongate slot 770 with a magnet positioned in or near the elongate slot 770 for magnetic engagement with the elongate metal plate 760. The elongate metal plate 760 protrudes from the barrel of the probe 710, providing a metal surface that is shaped to fit within the elongate slot 770 for magnetic engagement with the magnet. The magnet may be of any shape or size, with sufficient magnetic field strength to securely and releasably hold the probe 710. A physical engagement of the metal plate 760 within the elongate slot 770 is useful for preventing the probe 710 from rotating or disengaging from the magnet during handling of the instrument.

As shown, the elongate slot 770 is provided in a protruding portion 772 that protrudes only slightly from the rearward-facing portion of the holster 702 and thereby provides another example of a low-profile accessory storage device that does not interfere with a typical user's grip. Alternatively, the elongate slot 770 can be provided with an opening that is coplanar with or in a recessed area disposed within the rearward-facing portion of a holster, housing, or cover, to provide an even lower-profile accessory storage device.

While illustrative embodiments have been illustrated and described above, it will be appreciated that various changes can be made therein without departing from the spirit and scope of the disclosure. Therefore, the illustrated and described embodiments are to be considered as exemplary only and the invention itself should be evaluated only as defined in the claims.

The embodiments of the disclosure in which an exclusive property or privilege is claimed are defined as follows:

1. A holster for a portable test instrument, the holster comprising:
a frontward-facing portion configured to receive a portable test instrument;
a rearward-facing portion that defines a rearward plane of the holster; and
a low-profile accessory storage device configured to receive at least a portion of an accessory of the portable test instrument and releasably attach the accessory to the holster, the low-profile accessory storage device being disposed within the rearward-facing portion such that the low-profile accessory storage device does not extend beyond the rearward plane of the holster.

2. The holster of claim 1, wherein the rearward-facing portion comprises a perimeter edge that defines the rearward plane of the holster.

3. The holster of claim 2, wherein the perimeter edge comprises a perimeter ridge, and the rearward plane is defined by an upper portion of the perimeter ridge.

4. The holster of claim 1, wherein the low-profile accessory storage device comprises an accessory hanger.

5. The holster of claim 4, wherein the accessory hanger is configured to engage a clip disposed on the accessory to securely and releasably attach the accessory to the accessory hanger.

6. The holster of claim 4, wherein the accessory hanger comprises a keyed slot configured to engage a rail disposed on the accessory to securely and releasably attach the accessory to the accessory hanger.

7. The holster of claim 1, wherein the low-profile accessory storage device comprises a mounting hole.

8. The holster of claim 7, wherein the mounting hole is configured to engage a mounting post disposed on the accessory to securely and releasably attach the accessory to the holster.

9. The holster of claim 1, wherein the low-profile accessory storage device comprises a plurality of mounting holes configured to engage a corresponding plurality of mounting posts disposed on the accessory to securely and releasably attach the accessory to the holster.

10. The holster of claim 1, further comprising a tilt stand configured to accommodate releasable attachment of the accessory to the low-profile accessory storage device while the tilt stand is in an open position or a closed position.

11. The holster of claim 1, wherein the portable test instrument comprises a multimeter.

12. The holster of claim 1, wherein the accessory comprises a probe that is usable with the portable test instrument.

13. A portable test instrument comprising:
a frontward-facing portion;
a rearward-facing portion that defines a rearward plane of the portable test instrument; and
a low-profile accessory storage device configured to receive at least a portion of an accessory and releasably attach the accessory to the portable test instrument, the low-profile accessory storage device being disposed within the rearward-facing portion such that the low-profile accessory storage device does not extend beyond the rearward plane of the portable test instrument.

14. The portable test instrument of claim 13, wherein the rearward-facing portion comprises a rearward-facing portion of a housing or cover of the portable test instrument.

15. The portable test instrument of claim 13, wherein the low-profile accessory storage device comprises an accessory hanger.

16. The portable test instrument of claim 15, wherein the accessory comprises a clip, and the accessory hanger is configured to engage the clip to securely and releasably attach the accessory to the accessory hanger.

17. The portable test instrument of claim 13, wherein the low-profile accessory storage device comprises a plurality of mounting holes, and the accessory comprises a corresponding plurality of mounting posts, the mounting holes being configured to engage the mounting posts to securely and releasably attach the accessory to the portable test instrument.

18. The portable test instrument of claim 13, wherein the portable test instrument comprises a multimeter.

19. The portable test instrument of claim 13, wherein the accessory comprises a probe that is usable with the portable test instrument.

20. A holster for a portable test instrument, the holster comprising:
a frontward-facing portion configured to hold a portable test instrument;
a rearward-facing portion; and
a low-profile accessory storage device configured to receive at least a portion of an accessory of the portable test instrument and magnetically engage the accessory to releasably attach the accessory to the portable test instrument, the low-profile accessory storage device being disposed on the rearward-facing portion.
